(19) United States
(12) Patent Application Publication
(10) Pub. No.: US 2010/0100786 A1
(43) Pub. Date: Apr. 22, 2010

(54) SERIAL TEST MODE OF AN INTEGRATED CIRCUIT (IC)

(75) Inventors: Robert C. Dixon, Austin, TX (US); Robert DeVor, Austin, TX (US); Hien M. Le, Cedar Park, TX (US); Sarah Lynn Bird, Berkeley, CA (US)

Correspondence Address: IBM Austin IPLaw;(c/o), THE LAW OFFICE OF ROBERT A. MCLAUCHLAN, Post Office Box 26780, AUSTIN, TX, 78755, US

(73) Assignee: International Business Machines Corporation, Armonk, NY (US)

(21) Appl. No.: 12/253,783

(22) Filed: Oct. 17, 2008

(51) Int. Cl. G01R 31/3183; G06F 11/263

(52) U.S. Cl. 714/738; 714/E11.177

(57) ABSTRACT

A methodology to perform testing of integrated circuits (IC) wherein a reduced number of Input/Output (IO) pins may used to load testing patterns and capture test results from test structures after an IC has been installed in its intended application is provided. This methodology utilizes a software engine that receives and translates a parallel test pattern into serial data patterns operable to be provided on the reduced number of I/O pins. A serial process loader then loads the serial data patterns to the test structures within the IC. The IC receives the serial patterns and in turn translates them into parallel test patterns in order to apply the test patterns to the appropriate test structures. The results are captured and then translated into a serial format for communication from the IC to a test unit for analysis.

### BACKGROUND OF THE INVENTION

The present disclosure relates generally to the analysis of electronic circuits under various conditions, and more particularly, a system and method for analyzing circuitry within an integrated circuit (IC) within an application environment.

As the density of ICs increases, the potential problems associated with manufacturing and fabrication become greater and more difficult to detect. ICs are typically manufactured or fabricated on silicon wafers such as wafer 100 depicted in FIG. 1. Wafer testing involves an electrical test of test structures 104 on each die 102 of wafer 100 to determine if the die 102 will perform as desired.

During testing, before wafer 100 is sent to die preparation and packaging, all individual ICs that are present on the wafer are tested for functional defects with special test patterns. When all test patterns pass for a specific die 102, the dies that pass are remembered for later use during IC packaging. Sometimes a die 102 has internal spare resources available for repairing fault conditions. In this case, if the die does not pass some test patterns, spare resources can be used. If redundancy of failed die is not possible the die is considered faulty and is discarded. Non-passing circuits are typically marked on a wafermap. This wafermap categorizes the passing and non-passing dies. This wafermap is then sent to the die attachment process which then only picks up the passing dies.

In some very specific cases, a die that passes some but not all test patterns can still be used as a product, typically with limited functionality. The most common example of this is a microprocessor for which only one part of the on-die cache memory is functional. In this case, the processor can sometimes still be sold as a lower cost part with a smaller amount of memory and thus lower performance.

The contents of all test patterns and the sequence by which they are applied to an IC are called the test program. After IC packaging, a packaged chip will be tested again usually with the same or very similar test patterns.

As discussed above, ICs are tested as wafers or as packaged modules on dedicated testers. Patterns are supplied via the testers to test the operation of ICs. Once an IC is installed in its intended application environment, i.e. soldered to a circuit board, the ability to run the manufacturing test patterns is limited to those tests that may be initiated by other methods.

### BRIEF SUMMARY OF THE INVENTION

Embodiments of the present disclosure are directed to systems and methods that are further described in the following description and claims. Advantages and features of embodiments of the present disclosure may become apparent from the description, accompanying drawings and claims.

Embodiments of the present disclosure provide a method of performing serial testing of an integrated circuit (IC) which may be installed within its intended application. This involves loading a parallel test pattern to a first software module. The parallel test pattern is translated to a serial load pattern by the first software module. Then the serial load patterns may be loaded to the device under test such as the IC with a second software module. Testing of the device under test may be performed using the serial load patterns. The test results are captured for analysis. These test results may need to be translated from a serial output format to a parallel output format. Using a serial format in place of a parallel format for testing patterns may greatly reduce the number of pins required to apply test patterns to test structures within the die. This allows testing to be performed on die that have been packaged and assembled within printed circuit boards which may not have previously been possible. Furthermore since this testing might identify faults associated with die after they have been packaged and installed, where redundancy exists, these devices may be reconfigured to take advantage of redundant features within the die based on these test results.

Another embodiment of the present disclosure provides a computer-implemented method for performing testing of a device under test. This computer implemented method involves loading a parallel test pattern within a first software module. The parallel test pattern is translated to a serial load pattern(s) with the first software module. The serial load pattern is then loaded serially to a device under test wherein a reduced set of pins may be utilized to load the serial load pattern. Testing is performed using the serial load pattern(s) and the results are captured. The test results may be read from an output register in a serial format and then be translated to a parallel format wherein the parallel test results may be processed or analyzed using a software module similar to that available in a wafer probe or testing device.

Yet another embodiment provides an IC operable to be tested following assembly and installation using a reduced pin count. This IC includes a serial input register with which to receive serial test patterns and an input register operable to receive parallel test patterns. A multiplexor then selects between the serial test pattern and the parallel test pattern based on a testing environment flag. A test control unit directs either the serial output register or parallel output register to provide test patterns to test structures within the IC based on the testing environment flag. The test structures then execute the supplied test pattern and results are captured. These test results may then be provided in either a serial or a parallel format based on the testing environment flag to an external testing device for analysis.

Yet another embodiment provides a system operable to implement multi-mode testing of an IC. This system includes a plurality of input pins on the IC. A first sub-set of input pins couple to a serial input register operable to receive a serial test pattern. The second sub-set of input pins couple to a parallel input register operable to receive a parallel test pattern. A multiplexor selects between the serial test pattern and the parallel test pattern based on a testing environment flag which may be received on a testing environment pin. This pin indicates whether the testing of the IC will be done in a serial testing mode or a parallel testing mode. A test control unit then directs the desired output test pattern to test structures within the IC. The test control unit also directs the test structures to execute the test pattern and captures the results. Furthermore the test control unit may provide the test results in either a serial result pattern or a parallel result pattern based on the testing environment flag to an external testing device.

### BRIEF DESCRIPTION OF THE SEVERAL VIEWS OF THE DRAWINGS

For a more complete understanding of the present disclosure and the advantages thereof, reference is now made to the following description taken in conjunction with the accompanying drawings in which like reference numerals indicate like features and wherein:

FIG. 1 provides a top down view of a semiconductor wafer having die operable to be tested in accordance with embodiments of the present disclosure;

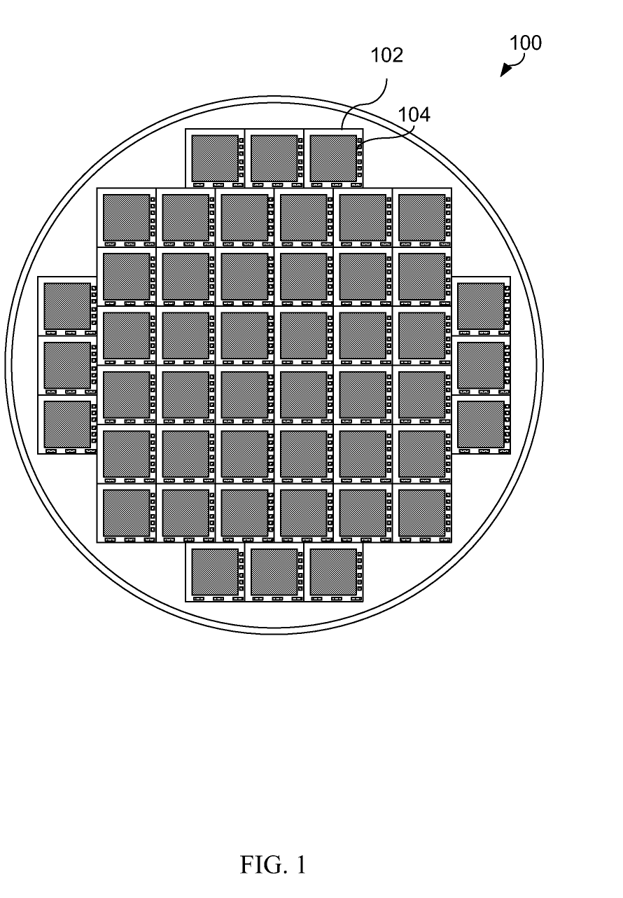

FIG. 2 provides a block diagram describing the architecture of a system on a chip (SoC) integrated circuit (IC) operable to be tested in accordance with embodiments of the present disclosure;

FIG. 3 provides a functional block diagram of a probe testing system;

FIG. 4 provides a system diagram wherein parallel test patterns are translated into serial test patterns in accordance with embodiments of the present disclosure;

FIG. 5 illustrates a software process that converts the parallel load test pattern to serial excitation data and serial expect data in accordance with embodiments of the present disclosure;

FIG. 6 provide a timing diagram that indicates a representative timing of the serial loading and unloading of data in accordance with embodiments of the present disclosure;

FIG. 7 provides a logic flow diagram of a methodology to perform serial testing of an IC in accordance with embodiments of the present disclosure; and

FIG. 8 provides a logic flow diagram of a methodology to perform multi-mode testing of an IC in accordance with embodiments of the present disclosure.

### DETAILED DESCRIPTION OF THE INVENTION

Preferred embodiments of the present disclosure are illustrated in the FIGs., like numerals being used to refer to like and corresponding parts of the various drawings.

Embodiments of the present disclosure provide a methodology to perform testing of integrated circuits (IC) wherein a reduced number of Input/Output (IO) pins may used to load testing patterns and capture test results from test structures after an IC has been installed in its intended application. This methodology utilizes a software engine that receives and translates a parallel test pattern into serial data patterns operable to be provided on the reduced number of I/O pins. A serial process loader then loads the serial data patterns to the test structures within the IC. The IC receives the serial patterns and in turn translates them into parallel test patterns in order to apply the test patterns to the appropriate test structures. The results are captured and then translated into a serial format for communication from the IC to a test unit for analysis.

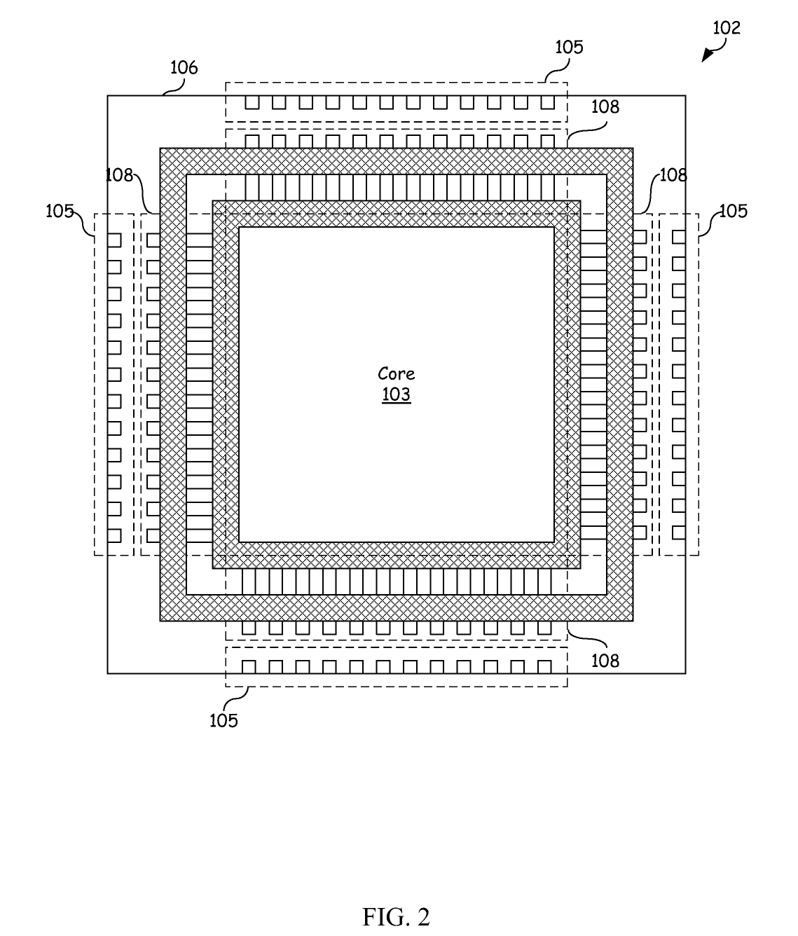

FIG. 2 depicts an IC or system on a chip (SoC) 102 that may include many logic and memory functions within the SoC. For example, IC 102 may include a CPU core, DSP core, DSP book, memory, control circuitry and analog/mixed signal circuitry. These are just examples of the types of systems or components that may be integrated into a signal chip.

Complexities are associated with the realization of SoC designs. Incorporating diverse components previously contained within a printed circuit board (PCB) involves confronting many design challenges. The discrete components may be designed for different entities using different tools. Other difficulties lie in fabrication. In general, fabrication processes of memory may differ significantly from those associated with logic circuits. For example, speed may be the priority associated with a logic circuit while current leakage of the stored charge is of priority for memory circuits. Therefore, multi-level interconnect schemes using five to six levels of metal are used for logic ICs in order to offer improved speed, while memory circuits may need only two to three levels.

In order for the IC to be useful, the IC must have physical connections to the outside world. Two extremes in IC development support different types of interfaces to external devices. Low cost packaging which supports low pin count is achieved with traditional wire bond attached chips. High cost packaging may support high pin count in the case of flip chips. In either case, I/O pins to support physical connections to the outside world are usually not dedicated to test structures not commonly used during normal operation of the die, as this would reduce the available pin count. Thus, pin count is not often available for test structures after the device has been installed in its intended application.

With wire bond attached chips such as IC 102 as illustrated in FIG. 2, pads 105, I/O cells 108 are placed at the edge of die 102. I/O cells 108 may be decoupled from core circuitry 103 by isolation structures. This ensures that electrical noise is not coupled into core 103. Additional circuitry for latch up and electrostatic discharge (ESD) protection may be placed within cells that form a ring around the dye which is called the I/O pad ring. Bond wire pads 105 are placed at the edge of the die outside I/O circuitry.

Traditional ICs fall into two general categories, core-limited and I/O or pad limited. A core-limited chip is one where the size of the chip is dependent on the amount of logic contained therein. The perimeter of the chip is more than sufficient to support the IO, clock, power, and ground bonding pads surrounding the core. A pad-limited IC's size is dictated by the bonding pads on the die's perimeter, wherein pads 105 are as close as possible, consistent with the IC's design rules. Thus, pad limited IC's often contain wasted open space within the die.

Advances in device density within the core have made it possible to reduce core size of IC devices. However, reduced I/O pad pitch (the pitch is typically defined as the repeat distance between adjacent I/O pads 105) has been hard to achieve because of packaging limitations.

Therefore, as a result, IC designs that are I/O intensive tend to have a die size significantly greater than that of the core.

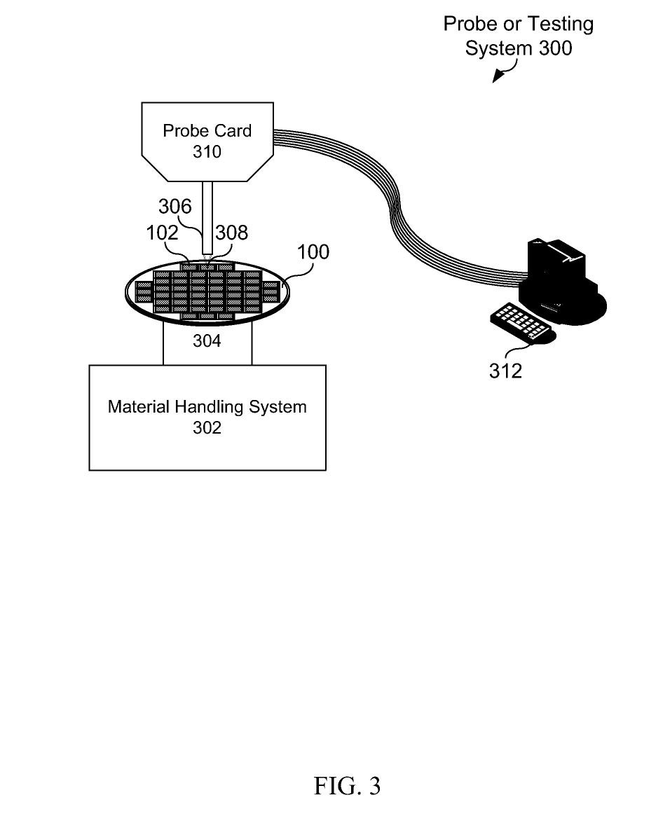

FIG. 3 provides a functional block diagram of a probe testing system 300. Probe testing system 300 includes a wafer handling system 302 to place wafer 100 on platform 304, a probe head 306, fine probe contacts 308, probe card 310 and a testing data collection system and control system 312. The testing data collection system and control system 312 may be executed on a pc or other like device to determine the likelihood that the die is good.

Wafer probe or test is the first time that die 102 are tested to determine proper operation of the IC. First, a material handling system 302 that takes wafers 100 from their carriers, loads them to a flat chuck or platform where the wafer is aligned and positioned precisely under a set of fine contacts 306 on a probe card 310. Secondly, each input-output or power pad on the die must be contacted by a fine electrical probe. This is done by a probe card, whose job is to translate the small individual die pad features into connections to the tester device 312. The functional tester or automatic test equipment (ATE) 312 is capable of functionally exercising all of the chip's designed features under software control. Any failure to meet the published specification is identified by the tester and the device is cataloged as a reject. The tester/probe card combination may be able to contact and test more than one die at a time on the wafer. This parallel test capability enhances productivity at wafer probe.

Embodiments of the present disclosure provide a means wherein functional pins may be shared within an IC to allow testing patterns to be loaded and the results captured from test structures after an IC has been installed in its intended application. A software engine may receive a parallel test pattern and translate the pattern into serial data patterns. A serial process loader then loads the serial data patterns to the device under test. The device under test receives the serial patterns and in turn translates them into parallel test patterns in order to apply the test patterns to the appropriate test structures. The results are gathered and then translated into a serial format for communication from the IC to a test unit for analysis.

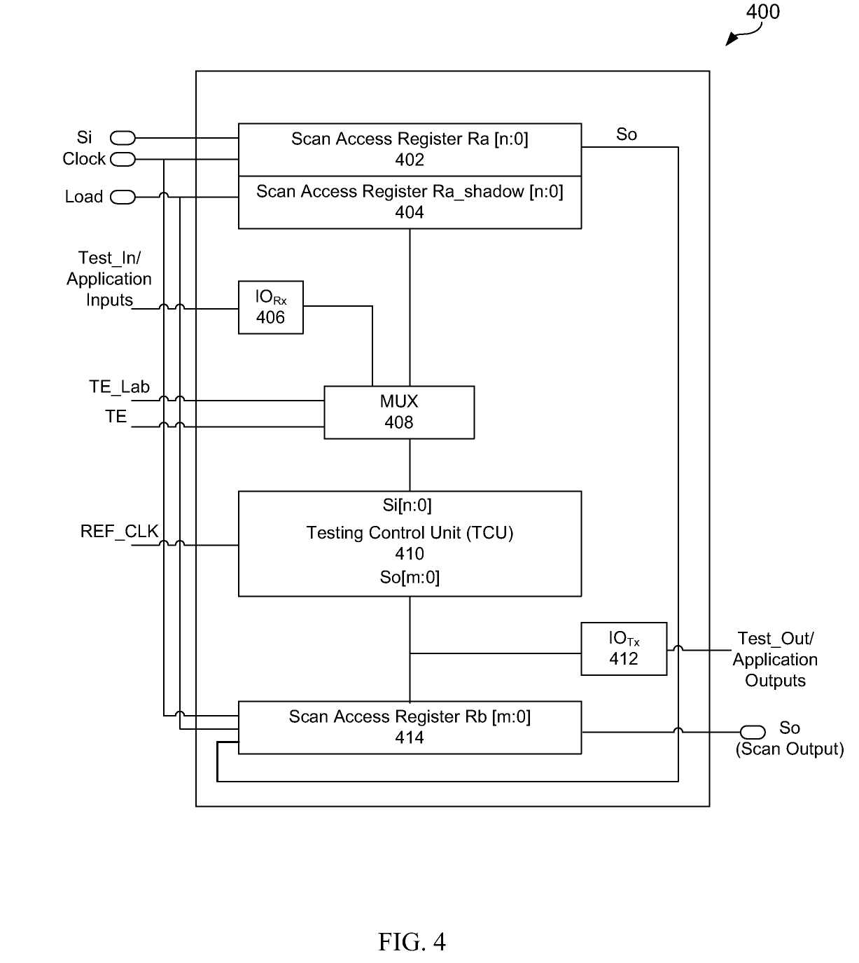

FIG. 4 provides a system diagram wherein parallel test patterns are translated into serial test patterns in accordance with embodiments of the present disclosure. The Si, So, Clock and Load signals may be on shared pins, for example, on existing Joint Test Action Group (JTAG) Interface Pins. System 400 includes scan access registers Ra 402 and Ra-Shadow 404, an I/O register 406, multiplexor 408, test controlling unit (TCU) 410, I/O output register 412 and a capture register 414.

Typically, a test interface multiplexes test signals onto functional I/O pins when an IC is in test mode. Test mode is entered by asserting a dedicated test enable pin, (TE). By adding an additional pin TE_LAB, the traditional test mode can have two distinct modes of operation. TE_LAB=0 results in the traditional tester test mode, while TE_LAB=1 results in the new test mode used in the application environment.

The two distinct modes of operation allow: 1) test pattern development and debug without utilizing high cost tester resources; 2) test failures to be analyzed in a lab environment; 3) application failures to be analyzed at the latch level which provides much greater flexibility than a JTAG scan; and 4) failure analysis to be performed in the application environment without removing a component from a circuit board.

In conventional component tests, TCU 410 is responsible for inputting pin test data and outputting pin test data in response to a tester delivered pattern. The tester delivers patterns by delivering pattern data in parallel and actions are taken in response to the component clock being asserted (ref_elk). The associated module pins are shared between test mode and functional mode, test_in are inputs and test_out are outputs in test mode.

Once a component is in an application environment, access to the shared I/O pins is limited due to connections to other components and circuit routing constraints. By adding a scan accessed register Ra 402 and a scan accessed register Rb 414, shared I/O are no longer required in a functional environment. This means the connections for testing, in one example, may be reduced to 5 pins from typical 32 in, 32 out plus control signals groups of pins. Scan accessed registers Ra 402 and scan accessed registers Rb 414 are serially loaded via a SI and a CLOCK input. The LOAD input copies the scanned data from Ra[n:0] to Ra_shadow[n:0] in a parallel manner, presenting Ra 402 to the TCU 410 and capturing TCU data to Rb 414.

Input te_lab is required to indicate to multiplexer 408 a special mode of test mode supporting the serial load of test patterns. Note that SI, CLOCK, LOAD and SO may be shared with other functional mode test interfaces, such as JTAG. At the same time, the test pattern has full access to these inputs for use in test patterns by accessing the replicated values in Ra[n:0] by scan.

During initialization, when power is first applied, Ra, Ra_shadow and Rb are in a random state. Since the test mode is defined by a vector out of Ra_shadow, Ra and Ra_shadow must initialize to clear the initial random state prior to the first ref_clk. Rb is self initializing upon execution of the first LOAD command to capture the first result data.

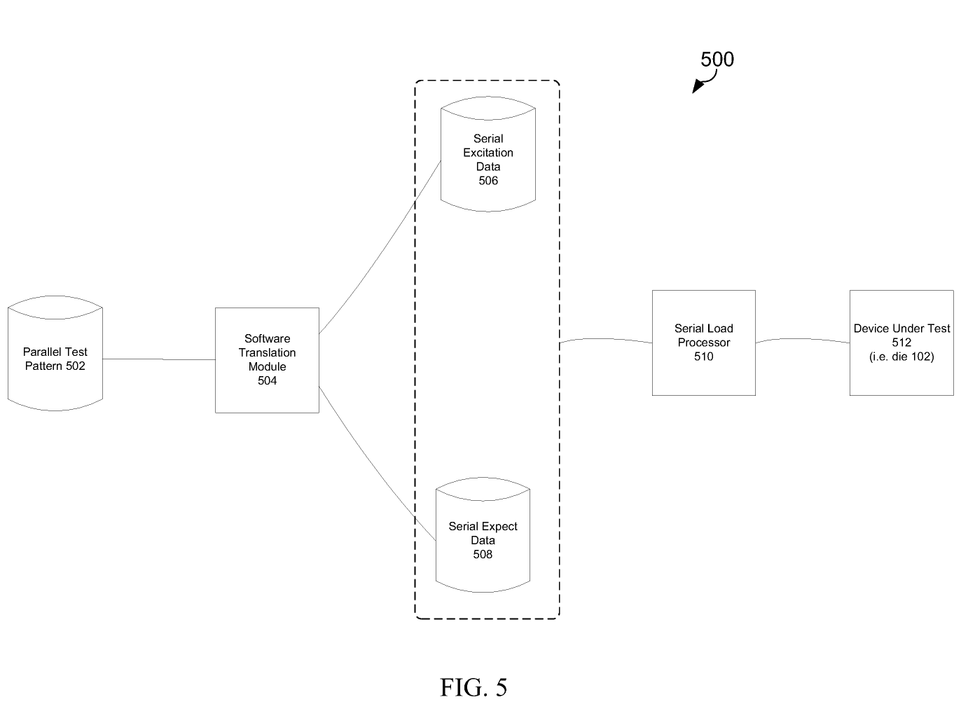

FIG. 5 illustrates a software process that converts the parallel load test pattern to serial excitation data and serial expect data in accordance with embodiments of the present disclosure. The serial load pattern data is loaded to the device to be tested by a second software program responsible for delivering the pattern, capturing results and providing periodic ref_clk cycles between each serial load corresponding to a set of parallel data.

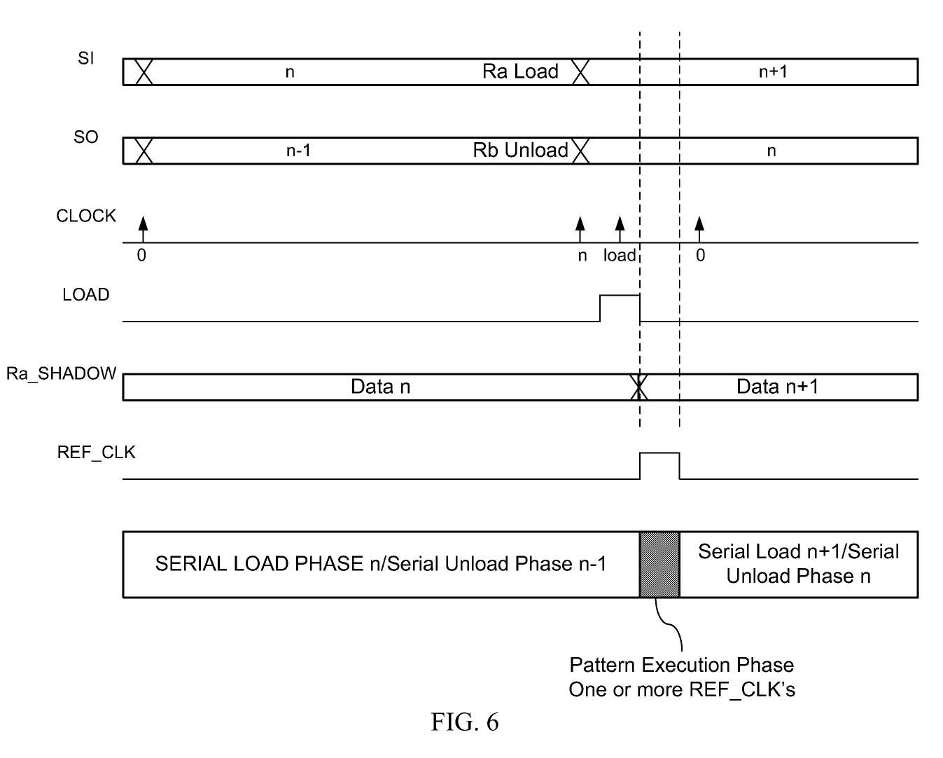

FIG. 6 provides a timing diagram that indicates a representative timing of the serial loading and unloading of data in accordance with embodiments of the present disclosure. The sequence defined repeats for each parallel test pattern. Clocks 0 to n represents register Ra being loaded via SI and register Rb being unloaded via SO as these registers are shifted. Clock load represents register Ra being copied to register Ra_SHADOW. Ref_clk is clocked to execute the command loaded to register Ra_shadow and to load register Rb with new result data.

The flowchart and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

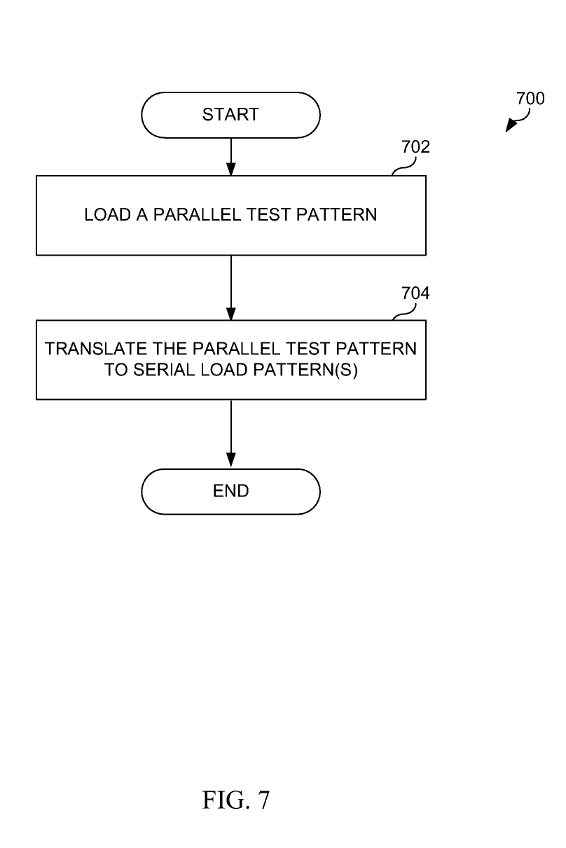

FIG. 7 provides a logic flow diagram for a method of performing serial pattern testing of an IC in accordance with embodiments of the present disclosure. Operations 700 begin in block 702 where a parallel test pattern may be loaded to a first software module. In Block 704 the parallel test pattern may be translated to serial load patterns by the first software module. The serial load patterns may be loaded to a device under test such as an IC using a second software module. Testing may be performed on the device under test using the serial load pattern. The tests results are captured within an output register of the device under test for analysis. The test results captured may be read in a serial format wherein an external device, such as a processing module capable of translating the serial test results to parallel tests results, then analyzes the parallel test results for the device under test. This results in an equivalent test being performed to that which would typically be performed at wafer probe or die packaging, even though the IC may be fully assembled, packaged and installed in an attended application such as a printed circuit board.

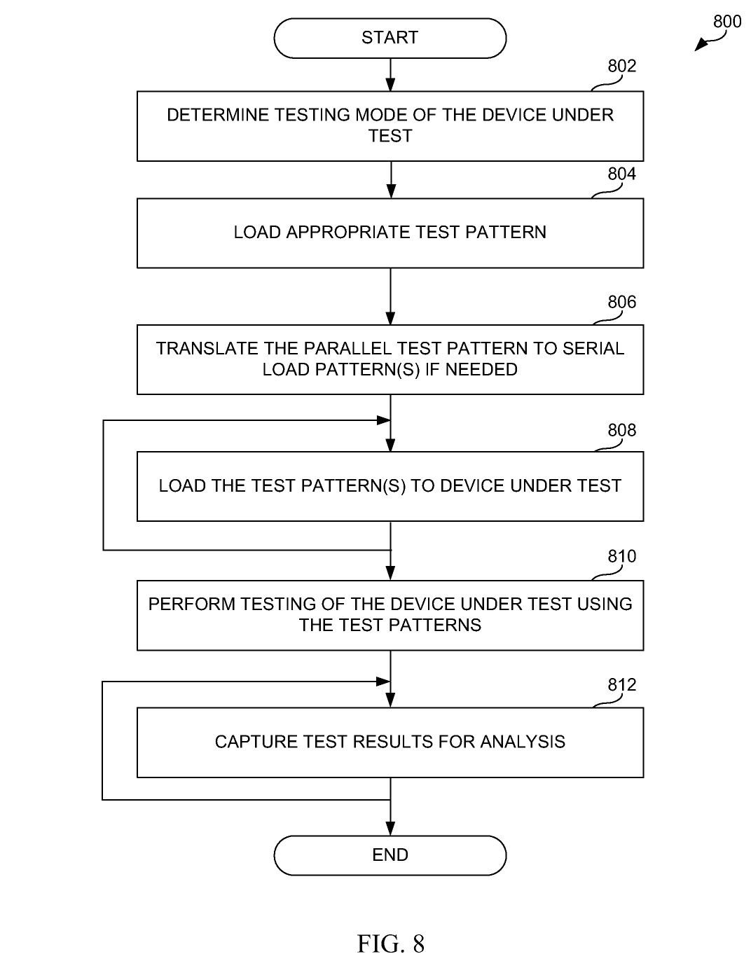

FIG. 8 provides a second logic flow diagram in accordance with embodiments of the present disclosure. Operations 800 begin with the determination of the testing mode of the device under a test. For example, this may in Block 802, involve the determination of the testing environment of the integrated circuit, whether the testing environment is at probe, in packaging or in an installed application. When the testing environment is in an installed application, use of a serial test pattern such as that discussed previously may be desirable in place of a parallel test pattern such that an appropriate test may be run with a reduced pin count. In Block 804 the appropriate test pattern whether it be serial or parallel is loaded. This may involve the translation of a parallel test pattern to a load pattern if needed in Block 806. The test patterns are then loaded to a device under test in Block 808. A control unit directs the testing of the device using the appropriate test patterns in Block 810. The output of Block 808 may be fed back as an additional input to Block 808. In Block 812, the test results are captured for analysis. The output of Block 812 may also be fed back as an additional input to Block 812. The captured test results may be translated from a serial to a parallel format if necessary in order to be unloaded from the die or integrated circuit to an external probe or testing device for analysis. By testing an installed device, it is possible when the device has redundancy capabilities, that the device may be reconfigured based on the test results. Additionally, this may be performed at any stage of the device's lifespan such that redundant features may be utilized throughout the product's lifespan.

Another embodiment may utilize a layout tool to implement IC design and layout circuit in accordance with embodiments of the present disclosure. To affect the layout of I/O interfaces, IC designers often use layout tools to ensure the compliance with and automate the layout of the various IC layers in accordance with the design rules associates with fabrication of a particular IC. Such a layout tool may be implemented with a computer or processing system. Processing systems can be any suitable computer-processing device that includes memory for storing and executing logic instructions, and is capable of interfacing with other processing systems. In some embodiments, processing systems can also communicate with other external components via an attached network. Various input/output devices, such as keyboard and mouse (not shown), can be included to allow a user to interact with components internal and external to processing systems. Additionally, processing systems can be embodied in any suitable computing device, and so include personal data assistants (PDAs), telephones with display areas, network appliances, desktops, laptops, X-window terminals, or other such computing devices. Logic instructions executed by processing systems can be stored on a computer readable medium, or accessed by/transmitted to processing systems in the form of electronic signals. Processing systems can be configured to interface with each other, and to connect to external a network via suitable communication links such as any one or combination of Ti, ISDN, or cable line, a wireless connection through a cellular or satellite network, or a local data transport system such as Ethernet or token ring over a local area network. The logic modules, processing systems, and circuitry described herein may be implemented using any suitable combination of hardware, software, and/or firmware, such as Field Programmable Gate Arrays (FPGAs), Application Specific Integrated Circuit (ASICs), or other suitable devices. The logic modules can be independently implemented or included in one of the other system components. Similarly, other components have been discussed as separate and discrete components. These components may, however, be combined to form larger, smaller, or different software modules, ICs, or electrical assemblies, if desired.

Layout tools are software suites or packages that may include layout, verification, places out, schematic capture, and industry standard database conversion and support tools. Layout tools facilitate the intricate layout design of ICs through the use of attached data bases. Layout tools in accordance with an embodiment of the present disclosure further facilitate IC design by allowing the die size to be reduced while considering testing after installation.

In summary, embodiments of the present disclosure provide a methodology to perform testing of ICs (IC) wherein a reduced number of Input/Output (IO) pins may used to load testing patterns and capture test results from test structures after an IC has been installed in its intended application. This methodology utilizes a software engine that receives and translates a parallel test pattern into serial data patterns operable to be provided on the reduced number of I/O pins. A serial process loader then loads the serial data patterns to the test structures within the IC. The IC receives the serial patterns and in turn translates them into parallel test patterns in order to apply the test patterns to the appropriate test structures. The results are captured and then translated into a serial format for communication from the IC to a test unit for analysis.

The flowchart and block diagrams in the FIGs. illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the FIGs. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The invention can take the form of an entirely hardware embodiment, an entirely software embodiment or an embodiment containing both hardware and software elements. In a preferred embodiment, the invention is implemented in software, which includes but is not limited to firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer readable medium can be any tangible apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk—read only memory (CD-ROM), compact disk—read/write (CD-R/W) and DVD.

A data processing system suitable for storing and/or executing program code will include at least one processor coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

As one of average skill in the art will appreciate, the term “substantially” or “approximately”, as may be used herein, provides an industry-accepted tolerance to its corresponding term. Such an industry-accepted tolerance ranges from less than one percent to twenty percent and corresponds to, but is not limited to, component values, IC process variations, temperature variations, rise and fall times, and/or thermal noise. As one of average skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of average skill in the art will also appreciate, inferred coupling (i.e., where one element is coupled to another element by inference) includes direct and indirect coupling between two elements in the same manner as “operably coupled”. As one of average skill in the art will further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method comprising:
loading a parallel test pattern to a first software module;
translating the parallel test pattern to serial load patterns with the first software module;
loading the serial load patterns to a device under test with a second software module;
performing testing of the device under test using the serial load patterns;
capturing test results within an output register of the device under test for analysis.

2. The method of claim 1, further comprising:
reading the test results within the output register wherein the test results are read in a serial format;
translating the serial test results to parallel test results with a third software module;
analyzing the parallel test results of the device under test.

3. The method of claim 1, further comprising determining a testing mode of the device under test, wherein:
test patterns are translated from parallel test pattern to serial load patterns in a serial testing mode; and
test patterns are loaded without translation in a parallel testing mode.

4. The method of claim 3, wherein the serial testing mode is performed on a device under test comprising comprises an integrated circuit (IC) that has been installed within a printed circuit board (PCB).

5. The method of claim 1, wherein the device under test comprises an integrated circuit (IC).

6. The method of claim 1, wherein the serial testing mode is performed on a device under test that has been installed within an intended application.

7. The method of claim 1, wherein a reduced set of Input/Output (IO) pins is used to:
load the serial load patterns to the device under test; and
read captured test results from the output register of the device under test for analysis.

8. A computer implemented method for performing testing of a device under test, the computer implemented method comprising:
loading a parallel test pattern to a first software module;
translating the parallel test pattern to serial load patterns with the first software module;
loading the serial load patterns to a device under test with a second software module;
performing testing of the device under test using the serial load patterns;
capturing test results of the device under test for analysis;
reading the test results from an output register of the device under test wherein the test results are read in a serial format;
translating the serial test results to parallel test results with a third software module;
analyzing the parallel test results for of the device under test.

9. The computer implemented method of claim 8, further comprising determining a testing mode of the device under test, wherein:
test patterns are translated from parallel test pattern to serial load patterns in a serial testing mode;
test results are translated from serial patterns to parallel patterns in a serial testing mode; and
test patterns and test results are loaded without translation in a parallel testing mode.

10. The computer implemented method of claim 9, wherein the serial testing mode is performed on a device under test comprising comprises an integrated circuit (IC) that has been installed within a printed circuit board (PCB).

11. The computer implemented method of claim 9, wherein the device under test comprises an integrated circuit (IC).

12. The computer implemented method of claim 9, wherein the serial testing mode is performed on a device under test that has been installed within an intended application.

13. The computer implemented method of claim 8, wherein a reduced set of Input/Output (IO) pins are used to:
load the serial load patterns to the device under test; and
read captured test results from the output register of the device under test for analysis.

14. An integrated circuit (IC), comprising:
a serial input register operable to receive a serial test pattern;
an input register operable to receive a parallel test pattern;
a multiplexer operable to select between the serial test pattern and the parallel test pattern based on a testing environment flag;
a test control unit operable to:
direct a serial output register or a parallel output register to provide test patterns to test structures within the IC based on the testing environment flag;
direct the test structures to execute the test patterns;
capture test results; and
provide the test results to an external testing device in a serial result pattern or parallel result pattern based on the testing environment flag.

15. The IC of claim 14, wherein the testing environment flag indicates testing of the IC in a serial testing mode or a parallel testing mode.

16. The IC of claim 15, wherein:
test patterns are translated from parallel test pattern to serial load patterns in the serial testing mode;
test results are translated from serial patterns to parallel patterns in the serial testing mode; and
test patterns and test results are loaded without translation in the parallel testing mode.

17. The IC of claim 15, wherein the serial testing mode is performed on the IC that has been installed within a printed circuit board (PCB).

18. The IC of claim 15, wherein the serial testing mode is performed on the IC that has been installed within an intended application.

19. The IC of claim 15, wherein a reduced set of Input/Output (IO) pins is used to:
load the serial load patterns to the IC; and
read captured test results from the output register of the device under test for analysis.

20. A system operable to implement multiple modes of testing of an integrated circuit (IC), the system comprising:
a plurality of input pins, wherein:
a first subset of input pins couple to a serial input register operable to receive a serial test pattern;
a second subset of input pins couple to a parallel input register operable to receive a parallel test pattern;
a multiplexer operable to select between the serial test pattern and the parallel test pattern based on a testing environment flag received on a testing environment pin, wherein the testing environment flag indicates testing of the IC in a serial testing mode or a parallel testing mode;
a test control unit operable to:
direct a serial output register or a parallel output register to provide test patterns to test structures within the IC based on the testing environment flag;
direct the test structures to execute the test patterns;
capture test results; and
provide the test results to an external testing device in a serial result pattern or parallel result pattern based on the testing environment flag.

21. The system of claim 20, wherein:
test patterns are translated from parallel test pattern to serial load patterns in the serial testing mode;
test results are translated from serial patterns to parallel patterns in the serial testing mode; and
test patterns and test results are loaded without translation in the parallel testing mode.
